(19) United States
(12) Patent Application Publication
(10) Pub. No.: US 2005/0170596 A1
(43) Pub. Date: Aug. 4, 2005

(54) Semiconductor device and method for manufacturing the same

(75) Inventor: Tae Woo Kim, Icheon (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Kangnam-ku (KR)

(21) Appl. No.: 11/024,845

(22) Filed: Dec. 30, 2004

(30) Foreign Application Priority Data
Dec. 30, 2003 (KR) 10-2003-0100924

(51) Int. Cl. H01L 21/336

(52) U.S. Cl. 438/305

(57) ABSTRACT

A semiconductor device and a method for manufacturing the same are disclosed. A pattern of a polysilicon layer for a gate electrode and another pattern of a polysilicon layer for a resistor are respectively formed on an active region of a salicide region and a device isolation film of a non-salicide region by respectively interposing a gate insulating film between the one pattern and the active region and between the other pattern and the device isolation film. A spacer is then formed at sidewalls of the polysilicon layer for the gate electrode and a salicide prevention film is formed to encircle the polysilicon layer for the resistor. Subsequently, source and drain regions are formed on the active region of the salicide region and a salicide layer is formed on the gate electrode and the source and drain regions of the salicide region.

### BACKGROUND OF THE INVENTION

1. Field of the Invention

The present invention relates to a semiconductor device and a method for manufacturing the same, and more particularly, to a semiconductor device and a method for manufacturing the same, in which process steps of forming a spacer in a self aligned silicide (hereinafter, referred to as “salicide”) region and a salicide prevention film in a non-salicide region are simplified.

2. Discussion of the Related Art

Generally, as a semiconductor device is more highly integrated, it is obtained more finely. Thus, a metal line including a gate electrode and source and drain regions of a MOS transistor decrease gradually.

As the gate electrode decreases, a sheet resistance of the gate electrode and its contact resistance increase, thereby deteriorating operational speed of the semiconductor device.

In spite of the circumstances, a request for a semiconductor device of high speed increases gradually. To fulfill such a request, methods for reducing the sheet resistance of the gate electrode and its contact resistance have been suggested. Of the methods, a method for forming a silicide layer having low specific resistance on the source and drain regions is widely used.

In the early silicide process, the step of forming a silicide layer on the gate electrode and the step of forming a silicide layer on the source and drain regions have been separately processed. In this case, there are problems in that the process steps are complicated and the manufacturing cost is high.

Recently, a salicide process has been employed to simplify the silicide process and reduce the manufacturing cost. The salicide process is performed in such a manner that the silicide layer is formed simultaneously on both the gate electrode and the source and drain regions by one process. In other words, in the salicide process, a high melting point metal layer is deposited simultaneously on a monosilicon layer, a polysilicon layer and an insulating film and then is thermally annealed. In this case, the high melting point metal layer on the monosilicon layer and the polysilicon layer is silicided to form a silicide layer while that on the insulating film remains without any silicide reaction. Afterwards, the high melting point metal layer remaining without any silicide reaction is removed by an etching process so that the silicide layer can remain only on the monosilicon layer and the polysilicon layer.

Thus, the existing salicide process based on a chemical vapor deposition process has been replaced with the aforementioned salicide process. Particularly, a titanium salicide process or a cobalt salicide process having excellent electrical resistance of metal or silicide has been widely used in a method for manufacturing a semiconductor device.

The related art semiconductor device, as shown in FIG. 1, includes a device isolation film 11 formed on a device isolation region to define an active region of a semiconductor substrate 10, a transistor 20 formed in the active region of a salicide region 13 of the semiconductor substrate 10, and a resistor 40 formed on the device isolation film 11 of a non-salicide region 15 of the semiconductor substrate 10.

The transistor 20 includes a gate insulating film 21 formed on the active region of the salicide region 13, a polysilicon layer 23 for a gate electrode formed on the gate insulating film 21, a spacer 27 of a nitride film formed at both sidewalls of the polysilicon layer 23 with a liner oxide film 25 interposed between the polysilicon layer 23 and the spacer 27, source and drain regions S/D separated from each other around the polysilicon layer 23 in the active region of the semiconductor substrate 10, and a salicide layer 31 formed on surfaces of the polysilicon layer 23 and the source and drain regions.

The resistor 40 further includes a gate insulating film 22 formed on the device isolation film 11 of the non-salicide region 15, a polysilicon layer 24 for a resistor formed on the gate insulating film 22, a spacer 28 of a nitride film formed at both sidewalls of the polysilicon layer 24 with a liner oxide film 26 interposed between the polysilicon layer 24 and the spacer 28, and a salicide prevention film 30 for preventing a salicide layer from being formed on the polysilicon layer 24.

However, the related art semiconductor device has several problems.

A fine error may occur during a photolithography process for forming a photoresist pattern (not shown) on the salicide prevention film 30 of the non-salicide region 15 to allow the salicide prevention film of the salicide region 13 to be removed while the salicide prevention film of the non-salicide region 15 to remain. In this state, if a wet etching process is performed, the edge of the salicide prevention film 30 of the non-salicide region 15, which is adjacent to the salicide region 13, is undercut by an etching solution for the etching process. For this reason, some of the polysilicon layer 24 is exposed.

As a result, in addition to the polysilicon layer 23 and the source and drain regions a salicide layer 31 is formed on the polysilicon layer 24. In this case, a resistance value of the resistor 40 is changed to an undesired value. This deteriorates reliability and characteristics of the semiconductor device. Moreover, yield of the semiconductor is reduced.

Furthermore, although not shown, if the active region of a narrow width is exposed at a portion where the salicide region 13 adjoins the non-salicide region 15, a salicide layer is formed abnormally on the active region of the above portion. In this case, salicide agglomeration occurs. This defect of the active region deteriorates reliability and characteristics of the semiconductor device. Moreover, yield of the semiconductor is reduced.

To solve the above problems, a dry etching process has been recently used when the salicide prevention film 30 is formed only on the non-salicide region 15. However, the dry etching process causes defects, such as plasma damage, on the surface of the active region of the semiconductor substrate 10. For this reason, a dopant of the source and drain regions in the salicide region is diffused during a thermal annealing process of the later salicide process. As a result, a threshold voltage of the transistor in the salicide region is varied and short channel effect (SCE) deeply occurs. This deteriorates reliability and characteristics of the semiconductor device. Moreover, yield of the semiconductor is reduced.

Further, in the related art method for manufacturing a semiconductor device, since the spacer, the salicide prevention film and the insulating film are deposited by a separate deposition process and the salicide prevention film remains only on the non-salicide region by the photolithography process, it is difficult to simplify the process steps.

### SUMMARY OF THE INVENTION

Accordingly, the present invention is directed to a semiconductor device and a method for manufacturing the same that substantially obviates one or more problems due to limitations and disadvantages of the related art.

An object of the present invention is to provide a semiconductor device and a method for manufacturing the same, in which a salicide layer is prevented from being formed on a non-salicide region of a semiconductor substrate and process steps of manufacturing a semiconductor device on a salicide region and the non-salicide region are simplified.

Another object of the present invention is to provide a semiconductor device and a method for manufacturing the same, in which a resistance value of a semiconductor device and its threshold voltage are stably maintained to improve reliability and characteristics of the semiconductor device.

Other object of the present invention is to provide a semiconductor device and a method for manufacturing the same, in which the manufacturing cost of a semiconductor device is reduced.

Additional advantages, objects, and features of the invention will be set forth in part in the description which follows and in part will become apparent to those having ordinary skill in the art upon examination of the following. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a semiconductor device includes a semiconductor substrate having a salicide region and a non-salicide region, a gate electrode formed on an active region of the salicide region with a gate insulating film interposed therebetween, a spacer formed at sidewalls of the gate electrode, source and drain regions formed on the active region and separated from each other around the gate electrode, a polysilicon layer for a resistor formed on a device isolation film of the non-salicide region, a salicide prevention film formed to encircle the polysilicon layer so as to avoid salicide reaction of the polysilicon layer for the resistor, and a silicide layer formed on the gate electrode and the source and drain regions.

Preferably, the salicide prevention film is formed of an insulating film having the same material as that of the spacer.

Preferably, the salicide prevention film is formed of a nitride film.

In another aspect, a method for manufacturing a semiconductor device includes the steps of forming a pattern of a polysilicon layer for a gate electrode on an active region of a salicide region of a semiconductor substrate and a pattern of a polysilicon layer for a resistor on a device isolation film of a non-salicide region of the semiconductor substrate by respectively interposing a gate insulating film between the one pattern and the active region and between the other pattern and the device isolation film, forming a salicide prevention film encircling the polysilicon layer for the resistor so as to avoid salicide reaction of the polysilicon layer for the resistor, along with forming a spacer at sidewalls of the pattern of the polysilicon layer for the gate electrode, forming source and drain regions on the active region of the salicide region, which are separated from each other around the polysilicon layer for the gate electrode, and forming a silicide layer on the polysilicon layer for the gate electrode and the source and drain regions.

Preferably, the step of forming the salicide prevention film along with the spacer includes depositing an insulating film on the entire surface of the semiconductor surface including the pattern of the polysilicon layer for the gate electrode and the polysilicon layer for the resistor, forming a pattern of an etching mask layer on the insulating film to be placed on the pattern of the polysilicon layer for the resistor, and etching the insulating film outside the pattern of the etching mask layer by an etching process having anisotropic etching characteristic.

Preferably, the spacer and the salicide prevention film are formed of nitride films.

Thus, in the present invention, the process steps of forming the spacer and the salicide prevention film can be simplified and the salicide layer can be prevented from being formed on the salicide region.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view illustrating a structure of a semiconductor device according to the related art;

FIG. 2 is a sectional view illustrating a structure of a semiconductor device according to the present invention; and

FIG. 3A to FIG. 3H are sectional views illustrating the manufacturing process for a semiconductor device according to the present invention.

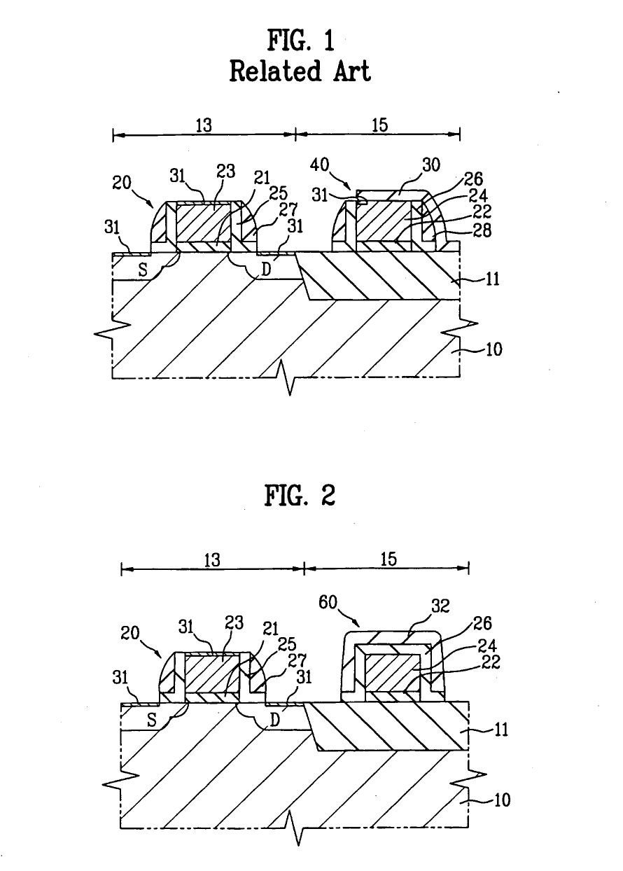

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a semiconductor device according to the present invention and a method for manufacturing the same will be described as follows.

FIG. 2 is a sectional view illustrating a structure of a semiconductor device according to the present invention. Referring to FIG. 2, a device isolation film 11 is formed on a device isolation region of a semiconductor substrate 10 to define an active region of the semiconductor substrate 10. Although the device isolation film 11 is formed by a shallow trench isolation (STI) process in the present invention, it may be formed by a local oxidation of silicon (LOCOS) process.

A transistor 20 is formed on the active region of a salicide region 13 of the semiconductor substrate 10, and a resistor 60 is formed in a non-salicide region 15 of the semiconductor substrate 10.

The transistor 20 includes a gate insulating film 21 formed on the active region of the salicide region 13, a polysilicon layer 23 for a gate electrode formed on the gate insulating film 21, a spacer 27 of a nitride film formed at both sidewalls of the polysilicon layer 23 with a liner oxide film 25 interposed between the polysilicon layer 23 and the spacer 27, source and drain regions S/D separated from each other around the polysilicon layer 23 in the active region of the semiconductor substrate 10, and a salicide layer 31 formed on surfaces of the polysilicon layer 23 and the source and drain regions.

The resistor 60 further includes a gate insulating film 22 formed on the device isolation film 11 of the non-salicide region 15, a polysilicon layer 24 for a resistor formed on the gate insulating film 22, and a salicide prevention film 32 formed to encircle the polysilicon layer 24 with a liner oxide film 26 interposed between the polysilicon layer 24 and the salicide prevention film 32, for preventing a salicide layer from being formed on the polysilicon layer 24. The salicide prevention film 32 has the same material as that of the spacer 27.

In the aforementioned semiconductor device, the spacer 27 and the salicide prevention film 32 are formed of insulating films deposited by one deposition process, for example, nitride films. When the spacer 27 is formed by an anisotropic dry etching process, the salicide prevention film 32 is formed to encircle the polysilicon layer 24 of the salicide region 15.

Therefore, in the present invention, the insulating films for the spacer of the salicide region and the salicide prevention film of the non-salicide region are deposited by one deposition process not a separate deposition process. In addition, since both the spacer and the salicide prevention film are formed by one dry etching process, the manufacturing process steps of the semiconductor device can be simplified and the manufacturing cost can be reduced.

Furthermore, since the salicide layer can be prevented from being formed on the polysilicon layer for the resistor of the salicide region, a resistance value of the resistor can stably be maintained. Moreover, since the spacer and the salicide prevention film are formed by one dry etching process, plasma damage on the surface of the active region of the salicide region can be avoided. Also, variation of a threshold voltage of the transistor in the salicide region can be controlled and short channel effect can be reduced. As a result, yield of the semiconductor device can be improved along with reliability and characteristics of the semiconductor device.

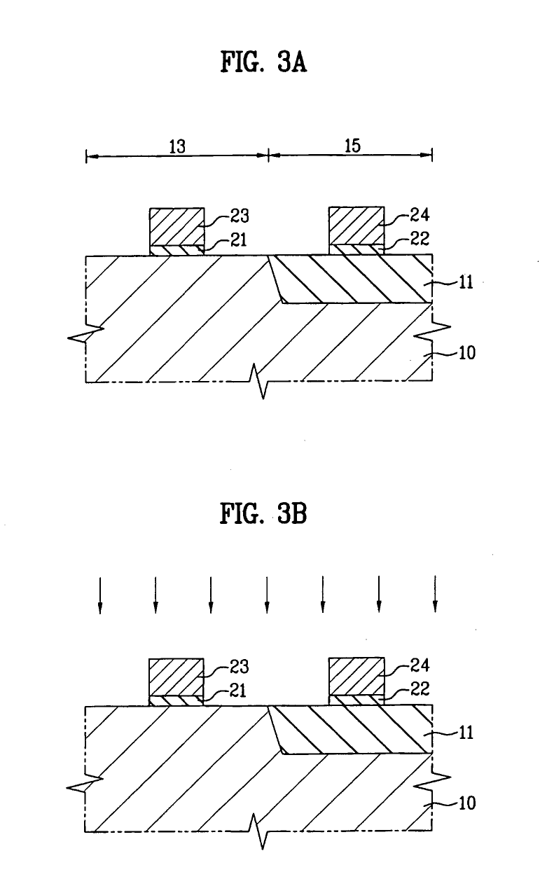

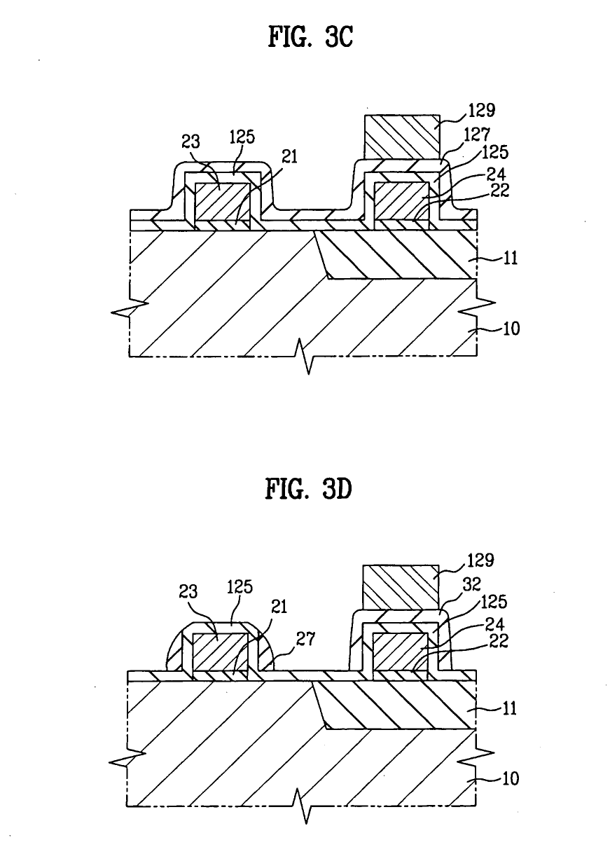

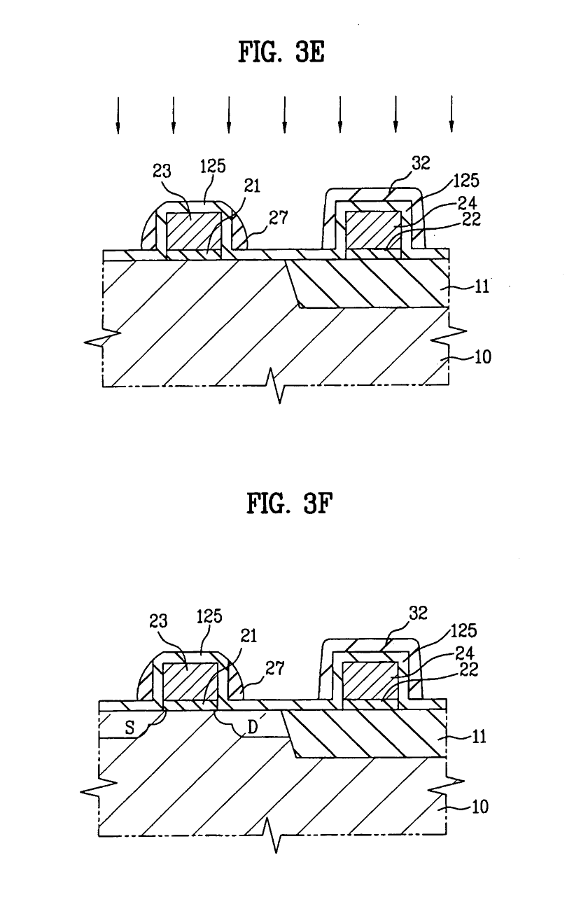

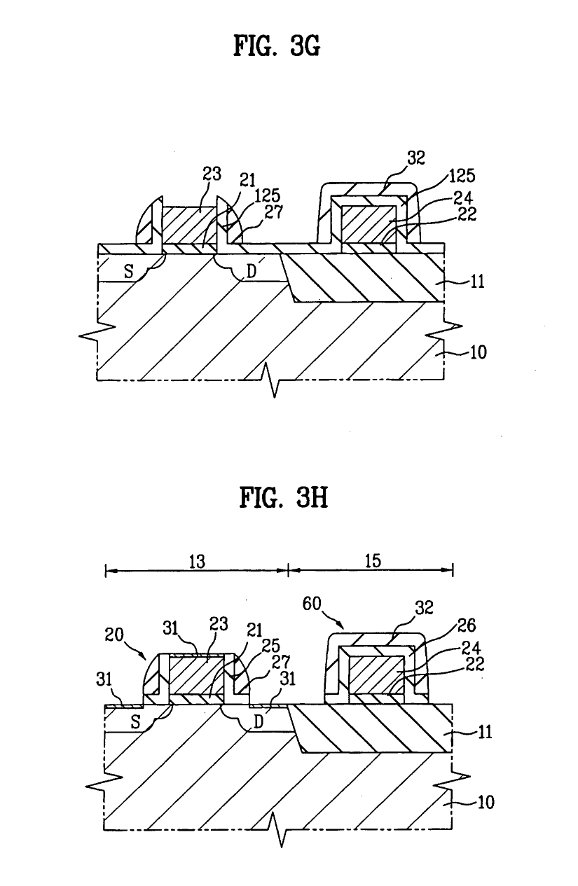

FIG. 3A to FIG. 3H are sectional views illustrating the manufacturing process for a semiconductor device according to the present invention.

As shown in FIG. 3A, a device isolation film 11 is formed on a device isolation region of a semiconductor substrate 10 to define an active region of a first conductive type monosilicon substrate, for example, a P type monosilicon substrate. Although the device isolation film 11 is formed in the drawing by a STI process, it is apparent that the device isolation film 11 may be formed by a LOCOS process.

The semiconductor substrate 10 is divided into a salicide region 13 and a non-salicide region 15. The non-salicide region 13 includes a portion for a resistor and an electrostatic discharge protection circuit.

Afterwards, a gate insulating film such as an oxide film is deposited on the active region of the semiconductor substrate 10 at a desired thickness, and a conductive layer for a gate electrode, such as a polysilicon layer, is deposited on the gate insulating film at a desired thickness. At this time, the oxide film used as the gate insulating film may be formed by a thermal oxidation process.

Patterns of a polysilicon layer 23 for the gate electrode and a gate insulating film 21 are formed on a gate electrode region of the active region of the salicide region 13 by a photolithography process. Patterns of a polysilicon layer 24 for the resistor and a gate insulating film 22 are also formed on a resistor region of the device isolation film 11 of the non-salicide region 15.

Subsequently, as shown in FIG. 3B, impurities for a lightly doped drain (LDD) region, for example, an N type impurities of a second conductivity, are lightly doped into the active region of the salicide region 13 using the pattern of the polysilicon layer 23 and the gate insulating film 21 as an ion implantation mask layer.

Meanwhile, while it has been described in the present invention that an N type MOS transistor is formed on the semiconductor substrate 10, a P type MOS transistor may be formed on the semiconductor substrate 10. Therefore, if the N type MOS transistor is formed, it is noted that an ion implantation mask layer such as a photoresist pattern (not shown) is formed on a portion (not shown) of the semiconductor substrate 10 for the P type MOS transistor other than a portion of the semiconductor substrate 10 for the N type MOS transistor by the photolithography process and the N type impurities are lightly doped thereinto. Likewise, if the P type MOS transistor is formed, it is noted that an ion implantation mask layer such as a photoresist pattern (not shown) is formed on a portion of the semiconductor substrate 10 for the N type MOS transistor other than a portion of the semiconductor substrate 10 for the P type MOS transistor by the photolithography process and the P type impurities are lightly doped thereinto. The order of ion implantation of the N type impurities and the P type impurities may be changed to each other.

As shown in FIG. 3C, a liner insulating film such as a liner oxide film 125 is deposited on the entire surface of the semiconductor substrate 10 including the polysilicon layers 23 and 24. An insulating film for a spacer 27 and a salicide prevention film 32 of FIG. 3D, such as a nitride film 127 having great etching selective ratio with the liner oxide film 125, is deposited on the liner oxide film 125. In this case, as shown in FIG. 3D, the liner oxide film 125 serves as an etching stopper film when the nitride film 127 is etched to form the spacer 27 and the salicide prevention film 32.

In the present invention as described above, since the insulating film for the spacer 27 and the salicide prevention film 32 is deposited by one deposition process, the manufacturing process steps can be simplified and the manufacturing cost can be reduced in comparison with the related art manufacturing process steps in which the spacer and the salicide prevention film are respectively deposited by a separate process.

Subsequently, an etching mask layer such as a photoresist pattern 129 is deposited on the polysilicon layer 24 by interposing the liner oxide film 125 and the nitride film 127 between the polysilicon layer 24 and the photoresist pattern 129. In this case, the photoresist pattern 129 is preferably wider than the polysilicon layer 24. This is to allow the salicide prevention film 32 to encircle the polysilicon layer 24, thereby avoiding salicide reaction of the polysilicon layer 24 for the resistor 60.

As shown in FIG. 3D, the nitride film 127 of FIG. 3C is etched using the photoresist pattern 129 as an etching mask layer by a dry etching process having anisotropic etching characteristic, such as a reactive ion etching process. Thus, the spacer 27 is formed at both sidewalls of the polysilicon layer 23 by interposing the liner oxide film 125 between the polysilicon layer 23 and the spacer 27. At this time, the liner oxide film 125 outside the spacer 27 is exposed. The salicide prevention film 32 encircling the polysilicon layer 24 is also formed.

In the present invention as described above, since the salicide prevention film 32 is formed along with the spacer 27, the manufacturing process steps can be simplified and the manufacturing cost can be reduced in comparison with the related art manufacturing process steps in which the spacer and the salicide prevention film are respectively formed by a separate etching process.

Further, since the salicide layer is prevented from being formed on the polysilicon layer 24 for the resistor in the non-salicide region, the resistance value of the resistor can stably be maintained.

Moreover, since the spacer 27 and the salicide prevention film 32 are formed by one dry etching process, plasma damage on the surface of the active region of the salicide region can be avoided. Thus, the impurities of the source and drain regions can be prevented from being diffused during a thermal annealing process for a later salicide reaction. This can control variation of the threshold voltage of the transistor in the salicide region and reduce short channel effect. As a result, reliability and characteristics of the semiconductor device can be improved. Moreover, yield of the semiconductor can be improved.

As shown in FIG. 3E, after the photoresist pattern 129 of FIG. 3D is removed, N type impurities for source and drain regions of the N type MOS transistor are heavily doped into the active region of the semiconductor substrate 10 using the polysilicon layer 23 and the spacer 27 as ion implantation mask layers.

Meanwhile, if the N type MOS transistor is formed on the semiconductor substrate 10, it is noted that an ion implantation mask layer such as a photoresist pattern (not shown) is formed on a portion (not shown) of the semiconductor substrate 10 for the P type MOS transistor other than a portion of the semiconductor substrate 10 for the N type MOS transistor by the photolithography process and the N type impurities are heavily doped thereinto. Likewise, if the P type MOS transistor is formed, it is noted that an ion implantation mask layer such as a photoresist pattern (not shown) is formed on a portion of the semiconductor substrate 10 for the N type MOS transistor other than a portion of the semiconductor substrate 10 for the P type MOS transistor by the photolithography process and the P type impurities are heavily doped thereinto. The order of ion implantation of the N type impurities and the P type impurities may be changed to each other.

Subsequently, as shown in FIG. 3F, the lightly doped N type impurities for the LDD region and the heavily doped N type impurities for the source and drain regions are diffused using a thermal annealing process such as a rapid thermal annealing process, so that the source and drain regions having an LDD structure, which are separated from each other around the polysilicon layer 23 for the gate electrode, are formed on the active region of the semiconductor substrate 10.

As shown in FIG. 3G, the liner oxide film 125 except the spacer 27 and the salicide prevention film 32 is removed by the wet etching process to expose the surfaces of the polysilicon layer 23 and the source and drain regions. At this time, since the spacer 27 and the salicide prevention film 32 have a great etching selective ratio with the liner oxide film 125, the photolithography process for forming an etching mask layer is not necessarily required.

Afterwards, as shown in FIG. 3H, a high melting point metal layer for the salicide layer is deposited on the entire surface of the semiconductor substrate 10 including the polysilicon layer 23 and the source and drain regions. Then, the high melting point metal layer undergoes salicide reaction by the thermal annealing process to form a salicide layer 31 on the polysilicon layer 23 and the source and drain regions. At this time, the high melting point metal layer on all the insulating films including the spacer 27 and the salicide prevention film 32 remains without salicide reaction.

Subsequently, the high melting point metal layer remaining without salicide reaction is removed by the etching process such as a wet etching process so that the salicide layer 31 on the polysilicon layer 23 and the source and drain regions remains and the spacer 27 and the salicide prevention film 32 are exposed. Thus, the process for manufacturing a semiconductor device according to the present invention is completed.

Since the salicide prevention film 32 prevents the salicide layer from being formed on the polysilicon layer 24, the resistance value of the resistor 60 can stably be maintained.

Therefore, since the salicide prevention film of the non-salicide region is formed along with the spacer of the salicide region, the manufacturing process steps of the semiconductor device can be simplified and the manufacturing cost can be reduced.

Furthermore, since the salicide prevention film is formed to encircle the polysilicon layer for the resistor of the non-salicide region, the salicide layer can be prevented from being formed on the polysilicon layer for the resistor, thereby stably maintaining the resistance value of the resistor.

Moreover, since the spacer and the salicide prevention film are formed by one dry etching process, plasma damage on the surface of the active region of the salicide region can be avoided. Thus, the impurities of the source and drain regions can be prevented from being diffused during the thermal annealing process for a later salicide reaction. This can control variation of the threshold voltage of the transistor in the salicide region and reduce short channel effect. As a result, yield of the semiconductor device can be improved along with reliability and characteristics of the semiconductor device.

As aforementioned, the semiconductor device and the method for manufacturing the same have the following advantages.

In the semiconductor device and the method for manufacturing the same according to the present invention, the patterns of the polysilicon layer for the gate electrode and the polysilicon layer for the resistor are respectively formed on the active region of the salicide region and the device isolation film of the non-salicide region by interposing the gate insulating film between them. The spacer is then formed at the sidewalls of the polysilicon layer for the gate electrode and the salicide prevention film is formed to encircle the polysilicon layer for the resistor. Subsequently, the source and drain regions are formed on the active region of the salicide region and the salicide layer is formed on the gate electrode and the source and drain regions of the salicide region.

Therefore, in the present invention, since the manufacturing process steps of forming the spacer and the salicide prevention film are simplified, the manufacturing cost can be reduced.

Further, since the salicide layer can be prevented from being formed on the polysilicon layer for the resistor, the resistance value of the resistor can stably be maintained.

Moreover, since plasma damage on the surface of the active region of the salicide region can be avoided, variation of the threshold voltage of the transistor in the salicide region can be controlled and short channel effect can be reduced. As a result, yield of the semiconductor device can be improved along with reliability and characteristics of the semiconductor device.

Korean Application No. P2003-100924 filed on Dec. 30, 2003, is hereby incorporated by reference in its entirety.

It will be apparent to those skilled in the art that various modifications and variations can be made in the present invention. Thus, it is intended that the present invention covers the modifications and variations of this invention provided they come within the scope of the appended claims and their equivalents.

1. A semiconductor device comprising:
a semiconductor substrate having a salicide region and a non-salicide region;
a gate electrode formed on an active region of the salicide region with a gate insulating film interposed therebetween;
a spacer formed at sidewalls of the gate electrode;
source and drain regions formed on the active region and separated from each other around the gate electrode;
a polysilicon layer for a resistor formed on a device isolation film of the non-salicide region;
a salicide prevention film formed to encircle the polysilicon layer so as to avoid salicide reaction of the polysilicon layer for the resistor; and
a silicide layer formed on the gate electrode and the source and drain regions.

2. The semiconductor device of claim 1, wherein the salicide prevention film is formed of an insulating film having a same material as that of the spacer.

3. The semiconductor device of claim 2, wherein the salicide prevention film is formed of a nitride film.

4. A method for manufacturing a semiconductor device comprising:
forming a pattern of a polysilicon layer for a gate electrode on an active region of a salicide region of a semiconductor substrate and a pattern of a polysilicon layer for a resistor on a device isolation film of a non-salicide region of the semiconductor substrate by respectively interposing a gate insulating film between one of the patterns and the active region and between the other of the patterns and the device isolation film;
forming a salicide prevention film encircling the polysilicon layer for the resistor so as to avoid salicide reaction of the polysilicon layer for the resistor, along with forming a spacer at sidewalls of the pattern of the polysilicon layer for the gate electrode;
forming source and drain regions on the active region of the salicide region, which are separated from each other around the polysilicon layer for the gate electrode; and
forming a silicide layer on the polysilicon layer for the gate electrode and the source and drain regions.

5. The method of claim 4, wherein the step of forming a salicide prevention film along with a spacer includes depositing an insulating film on an entire surface of the semiconductor surface including the pattern of the polysilicon layer for the gate electrode and the polysilicon layer for the resistor, forming a pattern of an etching mask layer on the insulating film to be placed on the pattern of the polysilicon layer for the resistor, and etching the insulating film outside the pattern of the etching mask layer by an etching process having anisotropic etching characteristic.

6. The method of claim 4, wherein the spacer and the salicide prevention film are formed of nitride films.

7. The method of claim 5, wherein the spacer and the salicide prevention film are formed of nitride films.

8. A method for manufacturing a semiconductor device comprising:
step for forming a pattern of a polysilicon layer for a gate electrode on an active region of a salicide region of a semiconductor substrate and a pattern of a polysilicon layer for a resistor on a device isolation film of a non-salicide region of the semiconductor substrate by respectively interposing a gate insulating film between one of the patterns and the active region and between the other of the patterns and the device isolation film;
step for forming a salicide prevention film encircling the polysilicon layer for the resistor so as to avoid salicide reaction of the polysilicon layer for the resistor, along with forming a spacer at sidewalls of the pattern of the polysilicon layer for the gate electrode;
step for forming source and drain regions on the active region of the salicide region, which are separated from each other around the polysilicon layer for the gate electrode; and
step for forming a silicide layer on the polysilicon layer for the gate electrode and the source and drain regions.

9. The method of claim 8, wherein the step for forming a salicide prevention film along with a spacer includes step for depositing an insulating film on an entire surface of the semiconductor surface including the pattern of the polysilicon layer for the gate electrode and the polysilicon layer for the resistor, step for forming a pattern of an etching mask layer on the insulating film to be placed on the pattern of the polysilicon layer for the resistor, and step for etching the insulating film outside the pattern of the etching mask layer by an etching process having anisotropic etching characteristic.

10. The method of claim 8, wherein the spacer and the salicide prevention film are formed of nitride films.

11. The method of claim 9, wherein the spacer and the salicide prevention film are formed of nitride films.
